(19) United States
(12) Patent Application Publication
(10) Pub. No.: US 2017/0117504 A1
(43) Pub. Date: Apr. 27, 2017

(54) FLEXIBLE DISPLAY AND MANUFACTURING METHOD THEREOF

(71) Applicants: BOE TECHNOLOGY GROUP CO., LTD., Beijing (CN); HEFEI BOE OPTOELECTRONICS TECHNOLOGY CO., LTD., Hefei (CN)

(72) Inventors: Sang Jin KIM, Beijing (CN); Daeoh OH, Beijing (CN)

(21) Appl. No.: 15/209,032

(22) Filed: Jul. 13, 2016

(30) Foreign Application Priority Data
Oct. 21, 2015 (CN) 201510689439.4

(51) Int. Cl. H01L 51/52; H01L 51/56; H01L 27/32

(52) U.S. Cl. CPC H01L 51/5256; H01L 27/3244; H01L 51/56; H01L 2251/5338; H01L 2227/323

(57) ABSTRACT

A flexible display and a manufacturing method thereof are provided. The flexible display includes a package structure. The package structure includes multiple package films which are stacked on top of each other. The multiple package films includes a plurality of layers of inorganic films. In at least one pair of adjacent package films included in the multiple package films, both of two contact surfaces which are contacted to each other are provided with concave-convex structures, respectively, and the concave-convex structures which are provided on the two contact surfaces are matched to each other. At least one of the pair of adjacent package films is inorganic film.

### TECHNICAL FIELD

Embodiments of the disclosure relate to a flexible display and a manufacturing method thereof.

### BACKGROUND

With development of displaying technology, flexible displays have been become a research focus in the field of display technology. The flexible displays have characteristics of flexibility, which can generate an experience for a specific user, and are applied to various fields of a portable electronic device, a wearable electronic device, a game device, a display screen in a shopping mall etc. The flexible displays are usually based on OLED (Organic Light-Emitting Diode) displaying technology.

### SUMMARY

An embodiment of the disclosure provides a flexible display, comprising a package structure, the package structure comprising multiple package films which are stacked on top of each other, and the multiple package films comprising a plurality of inorganic films, wherein in at least one pair of adjacent package films included in the multiple package films, both of two contact surfaces which are contacted with each other are provided with concave-convex structures, respectively, and the concave-convex structures which are provided on the two contact surfaces are matched to each other; and at least one package film in the pair of adjacent package films is inorganic film.

Another embodiment of the disclosure provides a method of manufacturing a flexible display, comprising forming a package structure, the package structure comprising multiple package films which are stacked on top of each other, and the multiple package films comprising a plurality of inorganic films, wherein in at least one pair of adjacent package films included in the multiple package films, both two contact surfaces which are contacted with each other are provided with concave-convex structures, respectively, and the concave-convex structures which are provided on the two contact surfaces are matched to each other; and at least one package film in the pair of adjacent package films is an inorganic film.

### BRIEF DESCRIPTION OF THE DRAWINGS

In order to clearly illustrate the technical solution of the embodiments of the invention, the drawings of the embodiments will be briefly described in the following; it is obvious that the described drawings are only related to some embodiments of the invention and thus are not limitative of the invention.

FIG. 1 is a structural schematic diagram of a flexible display;

FIG. 2 is a structural schematic diagram of a flexible display provided by an embodiment of the disclosure;

FIG. 3 is another structural schematic diagram of a flexible display provided by the embodiment of the disclosure;

FIG. 4 is a structural schematic diagram of a package structure of the flexible display provided by the embodiment of the disclosure; and

FIG. 5 is another structural schematic diagram of a package structure of the flexible display provided by the embodiment of the disclosure.

### DETAILED DESCRIPTION

In order to make objects, technical details and advantages of the embodiments of the invention apparent, the technical solutions of the embodiments will be described in a clearly and fully understandable way in connection with the drawings related to the embodiments of the invention. Apparently, the described embodiments are just a part but not all of the embodiments of the invention. Based on the described embodiments herein, those skilled in the art can obtain other embodiment(s), without any inventive work, which should be within the scope of the invention.

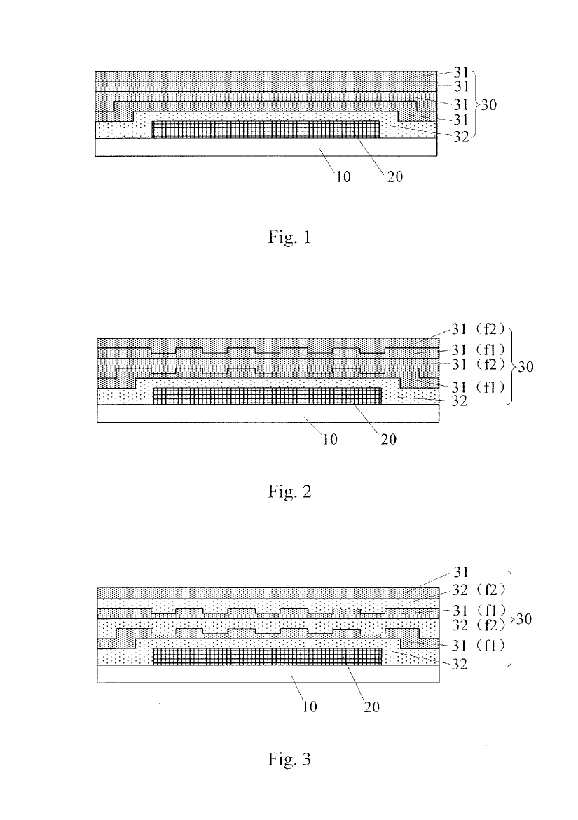

FIG. 1 is a structural schematic diagram of a flexible display. As illustrated in FIG. 1, the flexible display comprises an array substrate 10, an OLED light emitting structure 20 and a package structure 30. The OLED light emitting structure 20 comprises an anode layer, a light emitting layer and a cathode layer which are stacked sequentially. A material for forming the anode layer and the cathode layer is generally metal or metal oxide. A material for forming the light emitting layer is generally organic material, and the metal, the metal oxide and the organic material are easy to be oxidized in reacting with water and air. Thereby, the OLED light emitting structure is desired to be packaged by a package structure 30 having oxidation resistance. The package structure 30 is a structure where a layer of organic film 32 is stacked with a plurality of layers of inorganic films. The organic film is more flexible, which complies with requirements on flexibility of the display, but the oxidation resistance of the organic film 32 is poor, and thus the plurality of layers of inorganic films 31 having good oxidation resistance are required to be provided on the organic film 32. However, the flexibility of the inorganic film 31 is poor, and a stress between the films is increased due to the plurality of layers of inorganic films being provided, which causes the flexibility of the package structure 30 to be reduced, and the requirement on the flexibility of the display cannot be met.

An embodiment of the disclosure provides a flexible display. As illustrated in FIGS. 2 and 3, the flexible display comprises a package structure 30. The package structure 30 comprises a plurality of layers of package films which are stacked with each other. The plurality of layers of the package films comprises a plurality of layers of inorganic films 31. In at least one pair of adjacent layers of package films included in the plurality of layers of the package films, both contact surfaces which are contacted with each other have concave-convex structures, and the concave-convex structures provided on the two contact surfaces respectively are matched to each other. At least one of the pair of adjacent layers of the package films is the inorganic film 31. For example, the concave-convex structures provided on the two contact surfaces respectively being matched, means a pattern structure on one of the two contact surfaces is embedded into a concave structure on the other contact surface, and both sizes and shapes of the concave structure and the convex structure which are matched to each other are the same.

In the above-mentioned flexible display, the package structure 30 comprises a plurality of layers of inorganic films 31. Because the inorganic film 31 has good oxidation resistance, providing the plurality of layers of the inorganic films 31 make the package structure 30 to have good oxidation resistance, so that requirements on the oxidation resistance of the structure 30 are met. Furthermore, in the above mentioned flexible display, in at least one pair of adjacent layers of the package films included in the plurality of layers of the films of the package structure 30, the concave-convex structures which are matched to each other are provided on two contact surfaces which are contacted to each other, and at least one of the pair of adjacent layers of the films is the inorganic film, so that the contact surface of the inorganic film contacted with the adjacent film becomes a surface having the concave-convex structure of the embodiment and a contact area between the inorganic film and the adjacent layer is increased, which facilitates to counteract and disperse the stress between the two adjacent films, so that the flexibility of the inorganic film is increased, the flexibility of the package structure 30 is further improved, and the flexibility of the package 30 can meet requirements.

In following description, two layers of the package films included in “the pair of adjacent layers of the package films” are called a first package film f1 and a second film f2 respectively.

In the technical solution of this embodiment, after a material layer of the lower film layer (that is, the film layer which is formed firstly) of the first package film f1 and the second package film f2 is formed, the material layer is subject to a patterning process, to form the concave-convex structures, so that its surface is irregular. In a course of forming the upper film layer (that is, the film layer which is formed later) of the first package film f1 and the second package film f2, the upper film layer covers the irregular surface of the lower film layer, and an irregular surface will be formed naturally. That is, the contact surfaces of the first package film 31 and the second package film 32 have the concave-convex structures which are matched to each other.

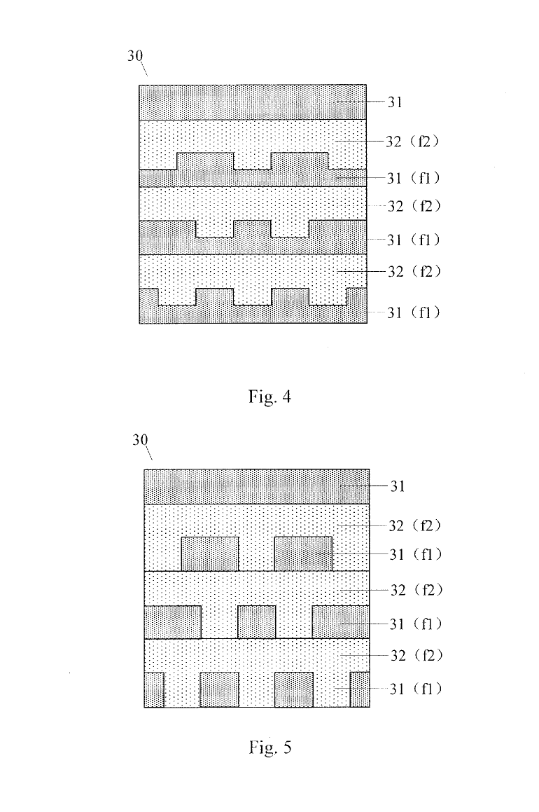

A case that the second package film f2 is located above the first package film f1 is taken as an example for illustration. The contact surface of the first package film f1 contacted with the second package film f2 can have concave and/or convex. The concave and/or the convex can be used as the concave-convex structure on the first package film f1. As illustrated in FIG. 4, both a height of the convex and a depth of the concave of the first package film f1 are less than a thickness of the first package film f1. That is, after the material layer of the first package film f1 is formed, the material of the first package film f1 on specific regions can be removed partially in the thickness direction, to form the concave-convex structure, so as to achieve a purpose of increasing contact areas of the first package film f1 and the second package film f2. As illustrated in FIG. 5, both the height of the convex of the first package film f1 and the depth of the concave of the film package film f1 can be equal to the thickness of the first package film f1. That is, after the material layer of the first package film f1 is formed, the material of the first package film f1 on specific regions can be removed completely in the thickness direction, to form the concave-convex structure, to achieve a purpose of increasing contact areas of the first package film f1 and the second package film f2.

It should be noted that, the above-mentioned “the thickness of the first package film f1” particularly refers to an original thickness of the first package film f1, and more particularly, it refers to a thickness of the material layer of the first package film f1. The above mentioned “specific regions” refers to regions where material needs to be removed in the regions on which the concave-convex structures are to be formed.

On the two contact surfaces of the first package film f1 and the second package film f2, the stresses produced on the opposite side walls of the convex (concave) are opposite to each other and thus the stresses counteract, and the contact areas of the first package film f1 and the second package film f2 are increased, which can disperse the stress between the first package film f1 and the second package film f2, to improve the flexibility of the first package film f1 and the second package film f2.

In this embodiment, if the second package film f2 is located above the first package film f1, as illustrated in FIGS. 3, 4 and 5, the first package film f1 can be the inorganic film 31, and the second package film f2 can be the organic film 32; alternatively, as illustrated in FIG. 2, both of the first package film f1 and the second package film f2 can be the inorganic film 31; alternatively, the first package film f1 is the organic film, and the second package film f2 is the inorganic film.

In the above mentioned technical solution, the first package film f1 and the second package film f2 constitute a pair of film layers which are matched to each other. In order to improve the flexibility of the package structure 30, multiple pairs of the film layers which are matched to each other are provided in the package structure 30.

Based on an inventive concept of the above mentioned technical solution which improves the flexibility by increasing contact areas of the film layers by providing concave-convex structures on the film layers, the arrangement of the organic film 32 and the inorganic film 31 of the package structure 30 can be designed according to actual need. For example, as illustrated in FIG. 2, the plurality of layers of the package films included in the package structure 30 can comprise a layer of organic film 32 and a plurality of layers of inorganic films 31 which are stacked on the layer of organic film 32 sequentially. Two contact surfaces which are contacted to each other of two adjacent layers of inorganic films can be provided with concave-convex structures which are matched to each other. Of course, two contact surfaces which are contacted to each other of the organic film 32 and the inorganic film 31 adjacent to the organic film 32 also can be provided with concave-convex structures which are matched to each other. As illustrated in FIG. 3, the plurality of layers of the package films included in the package structure 30 can comprise a plurality of layers of organic films 32 and a plurality of layers of inorganic films 31, the plurality of layers of the organic films 32 and the plurality of layers of the inorganic films 31 are stacked alternately, and two contact surfaces which are contacted to each other of the organic film 32 and the inorganic film 31 adjacent to the organic film 32 can be provided with concave-convex structures which are matched to each other.

In addition, a number of layers of the organic films 32 and inorganic films 31 respectively provided in the package structure 30 is not limited, and it can be determined according actual requirements on the flexibility and the oxidation resistance.

In some examples, sizes and numbers of the convex and the concave of the concave-convex structures corresponding to different regions of the flexible display can be designed differently according to different stresses on the different regions. For example, a stress on a middle region of the flexible display is generally larger than that of four corners of the flexible display, so a size and a number of the concave-convex structures corresponding to the middle region can be increased to largely counteract and disperse the stress of the middle region, so as to improve the flexibility of the middle region of the flexible display.

Refer to FIGS. 2 and 3, the flexible display provided by the embodiment comprises a substrate 10 and an OLED light emitting structure 20 in addition to the package structure 30. The substrate 10 and the package structure 30 constitute a closed space, and the OLED light emitting structure 20 is provided in the closed space, to avoid materials of the OLED structure 20 is oxidized by air.

In some examples, as illustrated in FIGS. 2 and 3, in the package structure 30, the package layer closest to the OLED structure 20 is an organic film and the package layer farthest away from the OLED structure 20 is an inorganic film.

In addition, FIGS. 2 and 3 only schematically illustrate one OLED structure. However, in the flexible display, a plurality of OLED structures can be included. The plurality of OLED structures is provided on the array substrate in an array.

In addition, the flexible display can comprise a variety of line structures and layer structures for driving the OLED light emitting structure. These structures can adopt any appropriate structure which has been known, which will not be repeated here.

In some examples, a material of the inorganic film of the package structure can be at least one selected from the group consisting of Al₂O₃, TiO₂, ZrO₂, MgO, HfO₂, Ta₂O₅, Si₃N₄, AlN, SiN, SiNO, SiO, SiO₂, SiOₓ, SiC and ITO.

In some examples, a material of the organic film of the package structure can be at least one selected from the group consisting of PET(polyethylene terephthalate), PEN(polyethylene naphthalate polyme), PC(polycarbonate), PI(polyimide), PVC(polyvinylchloride), PS(polystyrene), PMMA(polymethyl methacrylate), PBT(polybutylene terephthalate), PSO(polysulfone), PES(Polyether sulphone), PE(polyethylene), PP(polypropylene), silicone(polysiloxane), PA(polyamide), PVDF(polyvinylidene fluoride), EVA(ethylene-vinyl acetate copolymer), EVAL(ethylene-vinyl alcohol copolymer), PAN(polyacrylonitrile), PVAc(polyvinyl acetate), Parylene(Poly-p-xylene), Polyurea(polyurea), PTFE(polytetrafluoroethylene) and epoxy resin(epoxy resin) or a combination thereof.

It should be noted that the flexible display provided by the embodiments of the disclosure is applicable to a television set, a display, a movie screen, a cell phone, a tablet, a laptop, a digital frame, a navigator, and any product or component having displaying function.

Based on the above mentioned flexible display, the embodiment further provides a method of manufacturing the flexible display. Refer to FIGS. 2 and 3, the manufacturing method comprises a step of forming the package structure 30. The package structure 30 comprises a plurality of layers of package films which are stacked to each other. The plurality of layers of package films comprises a plurality of layers of inorganic films. In at least one pair of adjacent layers of package films included in the plurality of layers of package films, both of two contact surfaces which are contacted to each other are provided with concave-convex structures, and the concave-convex structures on the two contact surfaces are matched to each other. At least one of the pair of the adjacent layers of the package films is an inorganic film.

The package structure 30 of the flexible display manufactured by the above mentioned manufacturing method comprises a plurality of layers of inorganic films 31 which have good oxidation resistance, so that requirements on the oxidation resistance of the flexible display are met. Furthermore, in at least one pair of adjacent layers of the package films included in the package structure 30 of the flexible display, concave-convex structures which are matched to each other are provided on two contact surfaces which are contacted to each other, and at least one of the pair of adjacent layers of the films is the inorganic film, so that contact areas between the inorganic film and the adjacent layer are increased, which reduces the stress between the inorganic film and the adjacent film, in order to increase the flexibility of the inorganic film, and the flexibility of the flexible display can meet requirements.

Two layers of the package films included in the above mentioned “the pair of adjacent layers of the package films” are called a first package film f1 and a second film f2 respectively. The above mentioned manufacturing method can employ a patterning process to form the concave-convex structures on the contact surfaces of the first package film f1 and the second package film f2. Particularly, if the first package film f1 is formed before the second package film f2 is formed, a process of forming the concave-convex structures on the contact surfaces of the first package film f1 and the second package film f2 can comprises following steps:

Step 1: a material layer of the first package film f1 is formed.

In step S1, deposition, evaporation and spin-coating etc. can be adopted. The material of the first package film f1 is covered on the array substrate 10 of the OLED light emitting structure 20, to form the material layer of the first package film f1. The material of the first package film can be organic material or inorganic material.

Step 2: convex and/or concave are formed on the material layer of the first package film by adopting the patterning process, to form the first package film. Both of a height of the convex and a depth of the concave are less than or equal to a thickness of the material layer of the first package film.

In Step 2, if the material of the first package film f1 is the organic material, a mask of a pattern for the concave-convex structures of the first package film f1 can be adopted to expose the material layer of the first package film f1 directly. Then, the material layer of the first package film f1 is developed, to partially or totally remove the material of the first package film f1 in specific regions, to form the concave-convex structures on the material layer of the first package film f1. The film layer having the concave-convex structures is the first package film f1.

If the material of the first package film f1 is inorganic material, a photoresist layer can be covered on the material layer of the first package film f1, and then a mask having the concave-convex structures of the first package film f1 is adopted to expose and develop the photoresist layer, so that the pattern of the concave-convex structures of the first package film f1 is transferred to the photoresist layer. After that, the material layer of the first package layer f1 is etched by the photoresist layer as a mask, to partially or totally remove the material of the first package film f1 on specific regions, so as to form the concave-convex structures on the material layer of the first package film f1. The film layer having the concave-convex structures is the first package film f1. Alternatively, a mask having the concave-convex structures for the first package film f1 can be placed on the material layer of the first package film f1 directly, to etch the material layer of the first package film f1, so as to form the first package film f1.

In some examples, the material of the first package film f1 can be organic material and photosensitive organic material. Thus, a process of forming the concave-convex structures can be achieved by an exposure process. During the exposure process, if the mask which is employed is a half exposure mask, the material of the first package film f1 in specific regions can be removed totally and some of the material of the first package film 1 in the specific regions will be remained, as illustrated in FIG. 4. If the mask which is employed is a whole exposure mask, the material of the first package film f1 in specific regions can be removed totally, as illustrated in FIG. 5.

Step 3: the second package film f2 is formed on the first package film f1.

In step 3: deposition, evaporation and spin-coating etc. can be adopted. The material of the second package film f2 is covered on the first package film f1, to form the second package film f2. Because the concave-convex structures are provided on the first package film f1, that is, the surface of the first package film f1 is irregular, the surface of the second package film f2 which covers and contacts with the first package film f1 forms concave-convex structures naturally. The concave-convex structures of the first package film f1 and the concave-convex structures of the second package film f2 are matched to each other, so that contact areas of the first package film f1 and the second package film f2 are increased.

In order to improve the oxidation resistance and the flexibility of the package film structure 30, Step S1˜Step S3 can be repeated to form a plurality of pairs of the first package film f1 and the second package film f2 which are matched to each other.

The above mentioned embodiments are only exemplary, and not limitative to the scope of the disclosure. The scopes of the disclosure are defined by the accompanying claims.

This application claims the priority of Chinese Patent Application No. 201510689439.4 filed on Oct. 21, 2015, which is hereby incorporated entirely herein by reference.

1. A flexible display, comprising a package structure, the package structure comprising multiple package films which are stacked on top of each other, and the multiple package films comprising a plurality of inorganic films, wherein in at least one pair of adjacent package films included in the multiple package films, both of two contact surfaces which are contacted with each other are provided with concave-convex structures, respectively, and the concave-convex structures which are provided on the two contact surfaces are matched to each other; and at least one package film in the pair of adjacent package films is inorganic film.

2. The flexible display of claim 1, wherein the pair of adjacent layers in the package films are a first package film and a second package film, respectively, the contact surface of the first package film contacted with the second package film has at least one of a convex and a concave, and both a height of the convex and a depth of the concave are less than or equal to a thickness of the first package film.

3. The flexible display of claim 2, wherein the convex of one of the two contact surfaces of the first package film and the second package film which are contacted with each other is embedded into the concave of the other of the two contact surfaces.

4. The flexible display of claim 2, wherein the first package film is inorganic film and the second package film is organic film or inorganic film.

5. The flexible display of claim 2, wherein the first package film is organic film and the second package film is inorganic film.

6. The flexible display of claim 1, wherein the multiple package films comprise one organic film and a plurality of inorganic films which is stacked on the organic film sequentially.

7. The flexible display of claim 1, wherein the multiple package films comprise a plurality of organic films and a plurality of inorganic films, and the plurality of organic films and the plurality of inorganic films are stacked alternately.

8. The flexible display of claim 1, further comprising an array substrate and an OLED light emitting structure, the array substrate and the package structure constitute a closed space, and the OLED light emitting structure is provided in the closed space.

9. The flexible display of claim 8, wherein a package film of the package structure closest to the OLED light emitting structure is organic film, and a package films of the package structure farthest away from the OLED light emitting structure is inorganic film.

10. The flexible display of claim 8, wherein both a size and a number of the concave-convex structures of the package structure in a middle region of the array substrate are larger than those of the concave-convex structures of the package structure in corner regions of the array substrate.

11. A method of manufacturing a flexible display, comprising forming a package structure, the package structure comprising multiple package films which are stacked on top of each other, and the multiple package films comprising a plurality of inorganic films, wherein in at least one pair of adjacent package films included in the multiple package films, both two contact surfaces which are contacted with each other are provided with concave-convex structures, respectively, and the concave-convex structures which are provided on the two contact surfaces are matched to each other; and at least one package film in the pair of adjacent package films is an inorganic film.

12. The method of manufacturing the flexible display of claim 11, wherein the pair of adjacent package films are a first package film and a second package film, respectively, and forming the package structure comprises:
forming a material layer of the first package film;
forming at least one of a convex and a concave on the material layer of the first package film by a patterning process, to form the first package film, wherein both a height of the convex and a depth of the concave are less than or equal to a thickness of the first package film, and
forming the second package film on the first package film.

13. The method of manufacturing the flexible display of claim 12, wherein the first package film is inorganic film and the second package film is organic film or inorganic film.

14. The method of manufacturing the flexible display of claim 12, wherein the first package film is organic film and the second package film is inorganic film.

15. The method of manufacturing the flexible display of claim 11, wherein the multiple package films comprise an organic film and a plurality of layers of inorganic films which is stacked on the organic film sequentially.

16. The method of manufacturing the flexible display of claim 11, wherein the multiple package films comprise a plurality of organic films and a plurality of inorganic films, and the plurality of organic films and the plurality of inorganic films are stacked alternately.

17. The method of manufacturing the flexible display of claim 11, wherein the flexible display further comprises an array substrate and an OLED light emitting structure, the OLED light emitting structure is formed on the array substrate and the package structure is formed on a side of the array substrate where the OLED light emitting structure is formed to encapsulate the OLED light emitting structure.

18. The method of manufacturing the flexible display of claim 17, wherein a package film of the package structure closest to the OLED light emitting structure is organic film, and a package film of the package structure farthest away from the OLED light emitting structure is inorganic film.

19. The method of manufacturing the flexible display of claim 17, wherein both a size and a number of the concave-convex structures of the package structure in a middle region of the array substrate are larger than those of the concave-convex structures of the package structure in corner regions of the array substrate.
